(19) United States
(12) Patent Application Publication
(10) Pub. No.: US 2025/0107265 A1
(43) Pub. Date: Mar. 27, 2025

(54) LIGHT-EMITTING DEVICE AND PHOTOELECTRIC SENSOR

(71) Applicant: FOSHAN NATIONSTAR OPTOELECTRONICS CO., LTD., Guangdong (CN)

(72) Inventors: Mingjun ZHU, Foshan (CN); Zishan LU, Foshan (CN); Yurong LI, Foshan (CN); Canbiao WU, Foshan (CN); Yan CHEN, Foshan (CN); Haojie GUO, Foshan (CN); Danwei LI, Foshan (CN); Yinling ZHENG, Foshan (CN)

(21) Appl. No.: 18/758,619

(22) Filed: Jun. 28, 2024

(30) Foreign Application Priority Data
Sep. 22, 2023 (CN) 202322599026.X

(51) Int. Cl. H01L 31/173; H01L 31/02; H01L 31/0203; H01L 31/0232

(52) U.S. Cl. CPC H10F 55/255; H10F 77/407; H10F 77/50; H10F 77/933

(57) ABSTRACT

A light-emitting device includes a light-emitting assembly and a light-transmissive component. The light-emitting assembly includes a first bracket, a light-emitting element, and a first photosensitive element. The first bracket has a first surface and a second surface opposite to each other. Multiple first electrodes and multiple second electrodes are disposed at intervals on the first surface, and the light-emitting element and the first photosensitive element are disposed at intervals on the second surface. The light-emitting element is electrically connected to at least one of the multiple first electrodes. The first photosensitive element is electrically connected to at least one of the multiple second electrodes. The light-transmissive component includes a light-transmissive encapsulation layer and a light-concentrating portion which are sequentially disposed on a side of the light-emitting assembly facing away from the first surface, and the light-concentrating portion is disposed in correspondence with the light-emitting element.

### CROSS-REFERENCE TO RELATED APPLICATION(S)

This application claims priority to Chinese Patent Application No. 202322599026.X filed Sep. 22, 2023, the disclosure of which is incorporated herein by reference in its entirety.

### TECHNICAL FIELD

The present disclosure relates to the field of light-emitting technologies, and in particular, to a light-emitting device and a photoelectric sensor.

### BACKGROUND

In some fields such as the field of photoelectric sensors, the field of optical fiber communications, and the field of photolithography, the requirement for the light-emitting stability of a light-emitting assembly as the light source is relatively high. In the related art, a photosensitive element is usually added on a side of a light-emitting element of the light-emitting assembly to detect a light intensity of light emitted by the light-emitting element in real time. When the light intensity of the light emitted by the light-emitting element changes, the light intensity of the light emitted by the light-emitting element can be timely adjusted by the control circuit, so that the light intensity of the light emitted by the light-emitting element is more stably maintained within the ideal light intensity range.

However, in some of these fields, light rays emitted by the light-emitting element are usually made to approximate the parallel light, which causes the photosensitive element disposed on the side of the light-emitting element to be difficult to collect the sufficient amount of light rays emitted by the light-emitting element, and thus difficult to detect the change of the light intensity of the light emitted by the light-emitting element with high accuracy, thereby resulting in that the light intensity of the light emitted by the light-emitting element can not more stably maintained within the ideal light intensity range.

### SUMMARY

The present disclosure provides a light-emitting device, light emitted by the light-emitting device can approximate the parallel light, a photosensitive element of the light-emitting device can collect sufficient amount of light emitted by a light-emitting element, so that the light-emitting intensity of the light-emitting element can be stably maintained within the ideal light intensity range for a long time.

The present disclosure also provides a photoelectric sensor. The light-emitting device provided in the foregoing technical schemes is configured so that the precision of the photoelectric sensor is easily maintained at the relatively high level.

The present disclosure uses the following technical schemes.

According to a first aspect, a light-emitting device is provided. The light-emitting device includes a light-emitting assembly and a light-transmissive component. The light-emitting assembly includes a first bracket, a light-emitting element, and a first photosensitive element, the first bracket has a first surface and a second surface opposite to each other, multiple first electrodes and multiple second electrodes are disposed at intervals on the first surface, the light-emitting element and the first photosensitive element are disposed at intervals on the second surface, the light-emitting element is electrically connected to at least one of the multiple first electrodes, and the first photosensitive element is electrically connected to at least one of the multiple second electrodes. The light-transmissive component includes a light-transmissive encapsulation layer and a light-concentrating portion, the light-transmissive encapsulation layer is covered on a side of the light-emitting assembly facing away from the first surface, the light-concentrating portion is disposed on a side of the light-transmissive encapsulation layer facing away from the light-emitting assembly, the light-concentrating portion is disposed in correspondence with the light-emitting element, and the light-concentrating portion is configured to concentrate light rays emitted by the light-emitting element.

According to a second aspect, a photoelectric sensor is provided. The photoelectric sensor includes a second bracket, a second photosensitive element, and the light-emitting device according to the first aspect, where the second bracket carries a detection circuit, the second photosensitive element and the light-emitting device are disposed at intervals on the second bracket, the second photosensitive element and the light-emitting device are respectively electrically connected to the detection circuit, the light-emitting device is configured to emit light rays toward an outside of the photoelectric sensor to enable the light to be reflected through the external environment towards the second photosensitive element.

### BRIEF DESCRIPTION OF DRAWINGS

The present disclosure is further described in detail below with reference to the accompanying drawings and embodiments.

FIG. 1 is a perspective diagram of a light-emitting device according to an embodiment.

FIG. 2 is a top view of a light-emitting device according to an embodiment.

FIG. 3 is a structural exploded view of a light-emitting device according to an embodiment.

FIG. 4 is a sectional view of FIG. 2 taken along A-A.

FIG. 5 is a sectional view of FIG. 2 taken along B to B.

FIG. 6 is a partial structural diagram of a light-emitting device (a light-emitting element is disposed to be offset from a convex lens structure) according to an embodiment.

FIG. 7 is a partial structural diagram of a light-emitting device (a light-emitting element is disposed to be offset from a bowl-cup structure) according to an embodiment.

FIG. 8 is a polar coordinate light distribution curve graph of a light-emitting device according to an embodiment.

FIG. 9 is a rectangular coordinate light distribution curve graph of a light-emitting device according to an embodiment.

FIG. 10 is a perspective diagram of a light-emitting device (a light-transmissive component is omitted) according to an embodiment.

FIG. 11 is a top view of a light-emitting assembly (a light-emitting element and a first photosensitive element are omitted) according to an embodiment.

FIG. 12 is a bottom view of a light-emitting assembly, an insulation isolation layer, and an indication portion according to an embodiment.

FIG. 13 is a structural diagram of a photoelectric sensor according to an embodiment.

Reference list

| | |
|---|---|
| 1 | light-emitting device |
| 2 | light-emitting assembly |
| 20 | first bracket |
| 201 | first surface |
| 2011 | first electrode |
| 2012 | second electrode |
| 2013 | fifth electrode |
| 2014 | grounding electrode |
| 2015 | grounding extension portion |
| 202 | second surface |
| 2021 | third electrode |
| 2022 | fourth electrode |
| 2023 | first pad |
| 2024 | second pad |
| 203 | first conductive portion |
| 204 | second conductive portion |
| 21 | light-emitting element |
| 22 | first photosensitive element |
| 3 | light-transmissive component |
| 30 | light-transmissive encapsulation layer |
| 31 | light-concentrating portion |
| 310 | convex lens structure |
| 311 | bowl-cup structure |
| 311a | inner side surface |
| 311b | bottom surface |
| 4 | isolation layer |
| 40 | indication portion |
| 5 | photoelectric sensor |
| 50 | second bracket |
| 51 | second photosensitive element |

### DETAILED DESCRIPTION

In order to provide a better understanding for the technical problems to be solved, the technical schemes adopted, and the technical effects to be achieved by the present disclosure, the technical schemes of embodiments of the present disclosure will be further described in detail in connection with the accompanying drawings below. Apparently, the described embodiments are merely some embodiments of the present disclosure, rather than all of the embodiments. All other embodiments obtained by those skilled in the art based on the embodiments of the present disclosure without requiring creative efforts shall all fall in the scope of protection of the present disclosure.

In the description of the present disclosure, unless otherwise expressly specified and limited, the term “connected to each other”, “connected”, or “fixed” is to be construed in a broad sense, for example, as securely connected, detachably connected, or integrated; mechanically connected or electrically connected; directly connected to each other, indirectly connected to each other via an intermediary, internal connection between two elements, or interaction between two elements. For those of ordinary skill in the art, specific meanings of the preceding terms in the present disclosure may be understood based on specific situations.

In the present disclosure, unless otherwise expressly specified and limited, a first feature being “on” or “under” a second feature may include the first feature and the second feature being in direct contact, or may include the first feature and the second feature not being in direct contact but being in contact with each other through an additional feature therebetween. Moreover, the first feature being “on”, “above” or “over” the second feature includes the first feature being directly on, above or over and obliquely on, above or over the second feature, or simply indicates that the first feature is at a higher level than the second feature. The first feature being “under”, “below” or “underneath” the second feature includes the first feature being directly under, below or underneath and obliquely under, below or underneath the second feature, or simply represents that the first feature is at a lower level than the second feature.

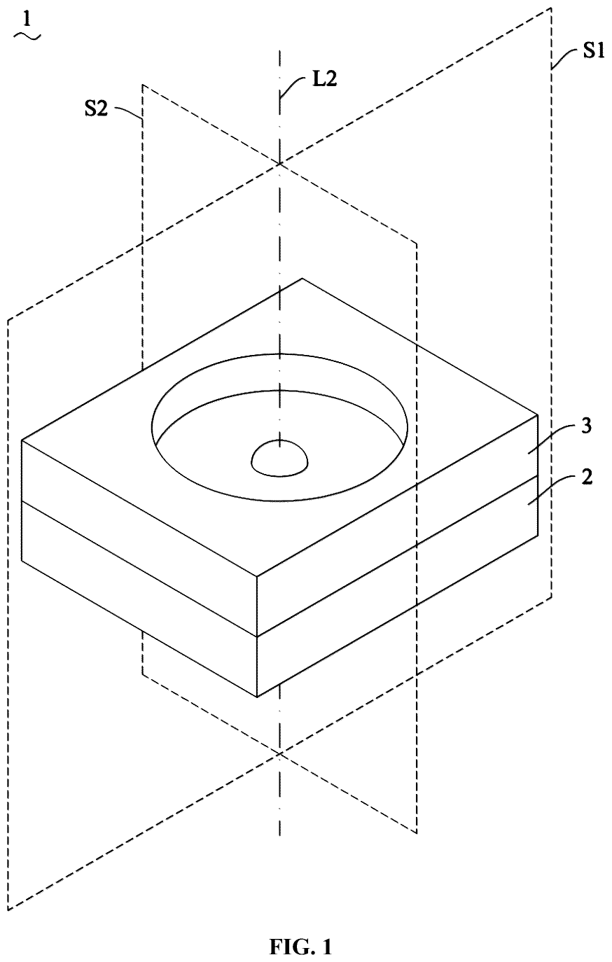

As shown in FIG. 1 to FIG. 5, the present disclosure provides a light-emitting device 1, and the light-emitting device 1 includes a light-emitting assembly 2 and a light-transmissive component 3. The light-emitting assembly 2 includes a first bracket 20, a light-emitting element 21, and a first photosensitive element 22. The first bracket 20 has a first surface 201 and a second surface 202 opposite to each other. Multiple first electrodes 2011 and multiple second electrodes 2012 are disposed at intervals on the first surface 201. The light-emitting element 21 and the first photosensitive element 22 are disposed at intervals on the second surface 202. The light-emitting element 21 is electrically connected to a first electrode of the multiple first electrodes 2011. The first photosensitive element 22 is electrically connected to a second electrode of the multiple second electrodes 2012. The light-transmissive component 3 includes a light-transmissive encapsulation layer 30 and a light-concentrating portion 31. The light-transmissive encapsulation layer 30 is covered on a side of the light-emitting assembly 2 facing away from the first surface 201. The light-concentrating portion 31 is disposed on a side of the light-transmissive encapsulation layer 30 facing away from the light-emitting assembly 2, the light-concentrating portion 31 is disposed in correspondence with the light-emitting element 21, and the light-concentrating portion 31 is configured to concentrate light rays emitted by the light-emitting element 21.

Both the light-emitting element 21 and the first photosensitive element 22 are disposed on the first bracket 20, and the light-emitting element 21 and the first photosensitive element 22 are encapsulated together through the light-transmissive encapsulation layer 30 included in the light-transmissive component 3. On the one hand, the light rays emitted by the light-emitting element 21 may be propagated to the first photosensitive element 22 through the light-transmissive encapsulation layer 30, so that the first photosensitive element 22 can collect sufficient amount of light rays emitted by the light-emitting element 21. On the other hand, a relative position between the light-emitting element 21 and the first photosensitive element 22 can be stabilized; therefore, during the long-term use of the light-emitting device 1, the detection accuracy of the first photosensitive element 22 is not easily affected by the change in the relative position between the light-emitting element 21 and the first photosensitive element 22, so that the first photosensitive element 22 can stably and accurately detect the light-emitting element 21 for a long time, and the light-emitting intensity of the light-emitting element 21 can be stably maintained within the ideal light intensity range for a long time.

Further, the light-transmissive component 3 includes the light-concentrating portion 31 disposed on the side of the light-transmissive encapsulation layer 30 facing away from the light-emitting assembly 2, so as to concentrate the light rays emitted by the light-emitting element 21, so that light rays emitted by the light-emitting device 1 approximate parallel light without affecting the first photosensitive element 22 to collect the light rays emitted by the light-emitting element 21.

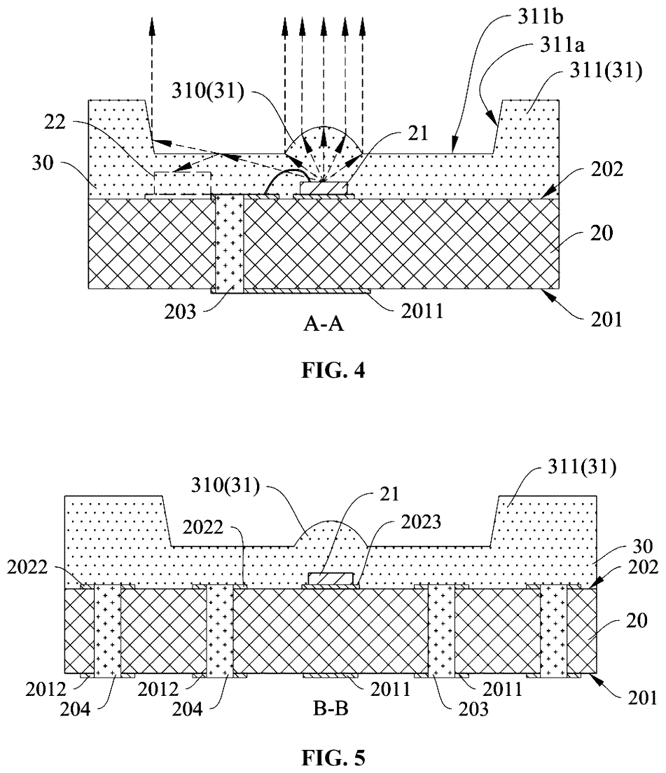

According to the Fresnel effect, when the light rays emitted by the light-emitting element 21 is emitted towards an interface between the light-transmissive encapsulation layer 30 and the air and an interface between the light-concentrating portion 31 and the air, the smaller the incident angle is, the more light rays are refracted, and the less light rays are reflected, instead, the larger the incident angle is, the less light rays are refracted, and the more light rays are reflected. Therefore, when the light rays are emitted towards the interface between the light-transmissive encapsulation layer 30 and the air and the interface between the light-concentrating portion 31 and the air, light rays with a relatively large incident angle, that is, light rays emitted by the light-emitting element 21 with a relatively large light emission angle, may be reflected in large numbers at this interface, and then may be propagated inside the light-transmissive encapsulation layer 30 to be emitted towards the first photosensitive element 22. The dashed lines and the arrows in FIG. 4 schematically show that the light rays emitted by the light-emitting element 21 with the relatively large light emission angle are emitted towards the interface between the light-transmissive encapsulation layer 30 and the air, where part of light rays are reflected at this interface and are emitted towards the first photosensitive element 22.

In addition, both the first electrode 2011 and the second electrode 2012 are disposed on the first surface 201, so that the light-emitting device 1 may be formed as a patch device, thereby allowing the light-emitting device 1 to be connected to an external bracket in a patch-like manner. Moreover, the first electrode 2011 and the second electrode 2012 are enabled to be electrically connected to an external circuit carried on the external bracket, thereby making the installation of the light-emitting device 1 simple.

Optionally, the light-emitting element 21 may be a light-emitting diode (LED) chip, and the light-emitting element 21 may be configured to emit light rays of a specific color. For example, red light is generally used as a light source in the photoelectric sensor. Therefore, the light-emitting element 21 may be configured to emit the red light, so as to be applicable to the photoelectric sensor. It should be understood that, in other implementation manners, the light-emitting element 21 may be further configured to emit light of other colors, such as blue light, green light, and white light. The specific colors of light rays emitted by the light-emitting element 21 and the number of light rays with different colors emitted by the light-emitting element 21 may be selected according to the practical application requirements, which are not specifically limited in the present application.

Optionally, the first photosensitive element 22 may include, but is not limited to, a photoresistor, a photodiode, and a phototransistor, so that the light rays may be received, and the current flowing through the first photosensitive element 22 changes with the change of the light rays.

Optionally, the light-transmissive encapsulation layer 30 and the light-concentrating portion 31 may be molded on the side of the light-emitting assembly 2 facing away from the first surface 201 through the secondary injection molding process, so that the light-emitting assembly 2 and the light-transmissive encapsulation layer 30 are connected to each other with a high density. Moreover, the light-transmissive encapsulation layer 30 is molded, and light-transmissive encapsulation layer 30 is connected to the light-emitting assembly 2, so that manufacturing steps of the light-emitting device 1 are simpler.

Optionally, a material of the light-transmissive encapsulation layer 30 is the same as a material of the light-concentrating portion 31, for example, the material may include, but is not limited to, a transparent resin and a transparent shadow-less adhesive. The light-transmissive encapsulation layer 30 and the light-concentrating portion 31 are integrally formed, therefore, the light-transmissive encapsulation layer 30 and the light-concentrating portion 31 do not need to be separately formed, so that the manufacturing steps of the light-emitting device 1 are simpler, and moreover, the light-transmissive encapsulation layer 30 and the light-concentrating portion 31 are connected to each other with a higher density. Further, no gap exists at a connection between the light-transmissive encapsulation layer 30 and the light-concentrating portion 31, so that a propagation direction of light rays at the connection between the light-transmissive encapsulation layer 30 and the light-concentrating portion 31 is not affected by the gap, and the controllability of the propagation direction of the light rays can be made higher.

The light-concentrating portion 31 may include, but is not limited to, multiple different optical structures that can implement the light-concentrating action. Optionally, the light-concentrating portion 31 may include a convex lens structure 310. An optical axis L2 of the convex lens structure 310 is close to a first central axis L1 of the light-emitting element 21, so that the convex lens structure 310 may receive the light rays emitted by the light-emitting element 21 and concentrate the light rays. The dashed lines and the arrows in FIG. 4 schematically show that the convex lens structure 310 is configured to receive part of light rays emitted by the light-emitting element 21 and condenses the part of light rays to emit the part of light rays.

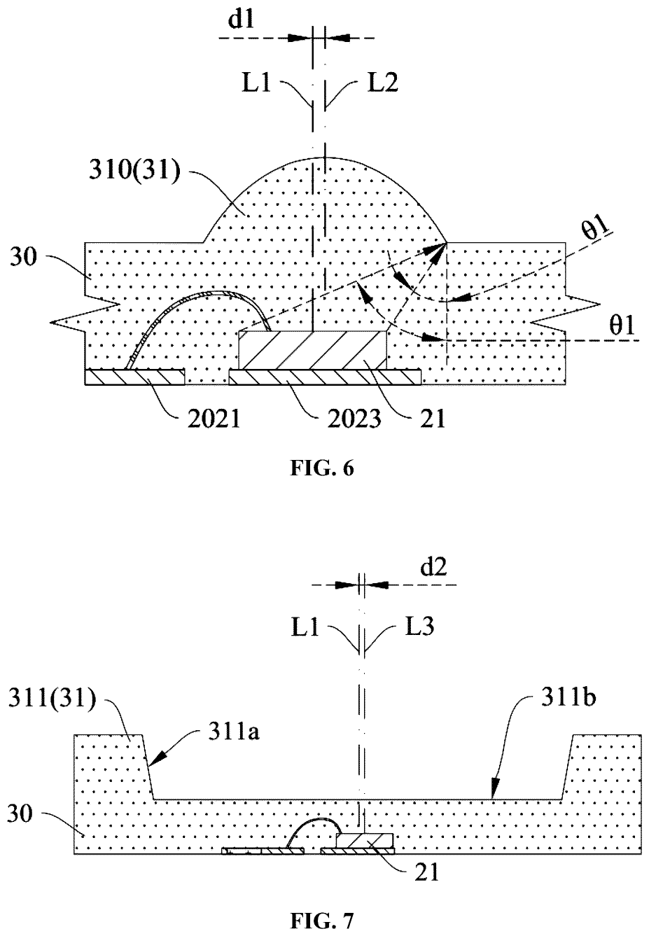

As shown in FIG. 6, in order to better enable the convex lens structure 310 to concentrate the light rays emitted by the light-emitting element 21 to form the parallel beam, the optical axis L2 of the convex lens structure 310 is at a distance d1 from the first central axis L1 of the light-emitting element 21 may be relatively small. Based on this, optionally, the distance d1 between the optical axis L2 and the first central axis L1 may satisfy: 0 mm≤d1≤0.05 mm. For example, the distance d1 may be 0 mm, 0.005 mm, 0.01 mm, 0.015 mm, 0.02 mm, 0.025 mm, 0.03 mm, 0.035 mm, 0.04 mm, 0.045 mm, or 0.05 mm and the like.

Preferably, the optical axis L2 of the convex lens structure 310 coincides with the first central axis L1 of the light-emitting element 21, in other words, the distance d1 between the optical axis L2 and the first central axis L1 may be 0 mm, thereby better enabling the convex lens structure 310 to concentrate the light rays emitted by the light-emitting element 21 to form the parallel beam.

To enable the convex lens structure 310 to receive more light rays emitted by the light-emitting element 21, so that the light intensity of the parallel light emitted by the light-emitting device 1 is relatively large, optionally, an outer peripheral edge of the convex lens structure 310 may be located on an outer periphery of the light-emitting element 21.

For the outer peripheral edge of the convex lens structure 310, light rays emitted from a position of the light-emitting element 21 closest to the edge is emitted towards the edge at a minimum light-emitting angle θ1, and an incident angle of the light rays at the edge is relatively small; light rays emitted from a position of the light-emitting element 21 furthest away from the edge is emitted towards the edge at a maximum light-emitting angle θ1, and an incident angle of the light rays at the edge is the largest. In view of refracting the received light rays at the edge to concentrate them into light rays of nearly parallel light, and moreover, the convex lens structure 310 as a whole is enabled to receive more light rays emitted by the light-emitting element 21, so as to achieve a higher light intensity of the parallel light emitted by the light-emitting device 1. Preferably, the light-emitting angle θ1 of the light rays received at the edge may satisfy: 20°≤θ1≤70°. For example, the light-emitting angle θ1 of the light rays received at the edge may be 20°, 25°, 30°, 35°, 40°, 45°, 50°, 55°, 60°, 65° or 70° and the like.

It should be noted that the foregoing “the light-emitting angle θ1 of the light rays received at the edge may satisfy: 20°≤θ1≤70°” refers to that different light rays received at the edge may have different light-emitting angles θ1, and a range of different light-emitting angles θ1 ranges from 20° to 70°. For example, in some implementation manners, the light-emitting angle θ1 may satisfy: 20°≤θ1≤63°, 22°≤θ1≤70°, 28°≤θ1≤65°, or 35°≤θ1≤67° and the like.

Optionally, the light-concentrating portion 31 may include an annular bowl-cup structure 311. A part of surfaces of the light-transmissive encapsulation layer 30 facing away from the light-emitting assembly 2 is formed as a bottom surface 311b of the bowl-cup structure 311. An inner side surface 311a of the bowl-cup structure 311 may be configured to receive light rays transmitted from the bottom surface 311b, and reflect the light rays to implement the effect of concentrating light. The dashed lines and the arrows in FIG. 4 exemplarily show part of light rays emitted by the light-emitting element 21 is emitted towards the interface (that is, the bottom surface 311b) between the light-transmissive encapsulation layer 30 and the air, where part of light rays is transmitted at this interface (that is, at the bottom surface 311b) and is emitted towards the inner side surface 311a of the bowl-cup structure 311, and the inner side surface 311a concentrates the part of light rays to emit them.

As shown in FIG. 7, in order to better enable the bowl-cup structure 311 to concentrate the light rays emitted by the light-emitting element 21 to form the parallel beam, a distance d2 between a second central axis L3 surrounding the inner side surface 311a of the bowl-cup structure 311 and the first central axis L1 of the light-emitting element 21 may be relatively small. Based on this, optionally, the distance d2 between the second central axis L3 and the first central axis L1 may satisfy: 0 mm≤d2≤0.05 mm, for example, the distance d2 may be 0 mm, 0.005 mm, 0.01 mm, 0.015 mm, 0.02 mm, 0.025 mm, 0.03 mm, 0.035 mm, 0.04 mm, 0.045 mm, or 0.05 mm and the like.

Preferably, the inner side surface 311a of the bowl-cup structure 311 may be disposed around the first central axis L1, in other words, the first central axis L1 may coincide with the second central line L3, and the distance d2 between the second central line L3 and the first central axis L1 may be 0 mm, so that the bowl-cup structure 311 is configured to concentrate the light rays emitted by the light-emitting element 21 to form the parallel beam.

Optionally, the bowl-cup structure 311 may be further configured to be connected to an end of an external optical fiber, so that a center of the end of the optical fiber is close to or aligned with the first central axis L1 of the light-emitting element 21, and the optical fiber can more effectively receive the light rays emitted by the light-emitting device 1.

Still optionally, the light-concentrating portion 31 may include a convex lens structure 310 and an annular bowl-cup structure 311, so as to concentrate light rays with a relatively small light-emitting angle of the light-emitting element 21 by using the convex lens structure 310, and concentrate light rays with a relatively large light-emitting angle of the light-emitting element 21 by using the bowl-cup structure 311, so that the light-concentrating portion 31 can concentrate more light rays emitted by the light-emitting element 21 to form the parallel beam, and further, the light intensity of the parallel light emitted by the light-emitting device 1 is relatively large.

Optionally, specific structures and setting positions of the convex lens structure 310 and the annular bowl-cup structure 311 may be referred to the foregoing technical schemes, and are not described herein again.

At this time, preferably, the inner side surface 311a of the bowl-cup structure 311 is spaced from the convex lens structure 310, and the inner side surface 311a correspondingly surrounds the outer periphery of the convex lens structure 310, in other words, the second central axis L3 of the inner side surface 311a coincides with the optical axis L2 of the convex lens structure 310, so that the bowl-cup structure 311 and the convex lens structure 310 have a relatively reasonable relative position, and the light-concentrating effect of the bowl-cup structure 311 and the convex lens structure 310 on the light rays emitted by the light-emitting element 21 can easily reach the better level.

Further, the optical axis L2 of the convex lens structure 310 coincides with the first central axis L1 of the light-emitting element 21, in other words, the optical axis L2, the first central axis L1 and the second central axis L3 are all coincided, so that both the convex lens structure 310 and the bowl-cup structure 311 concentrate the light rays emitted by the light-emitting element 21 to form the parallel beam.

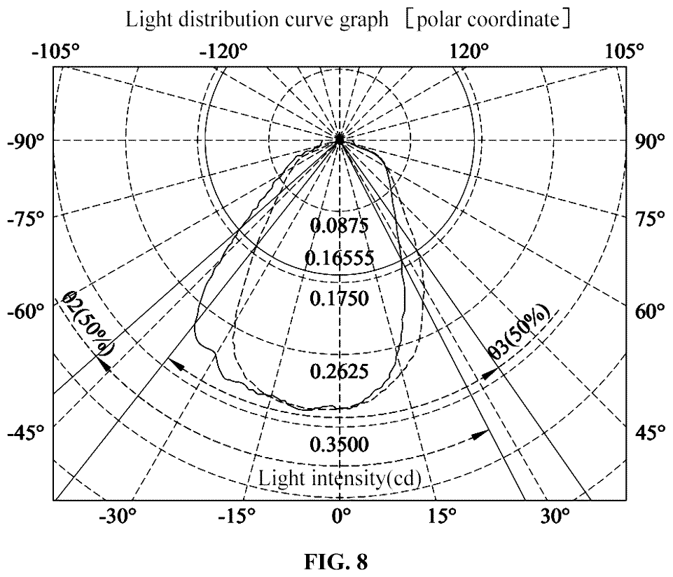

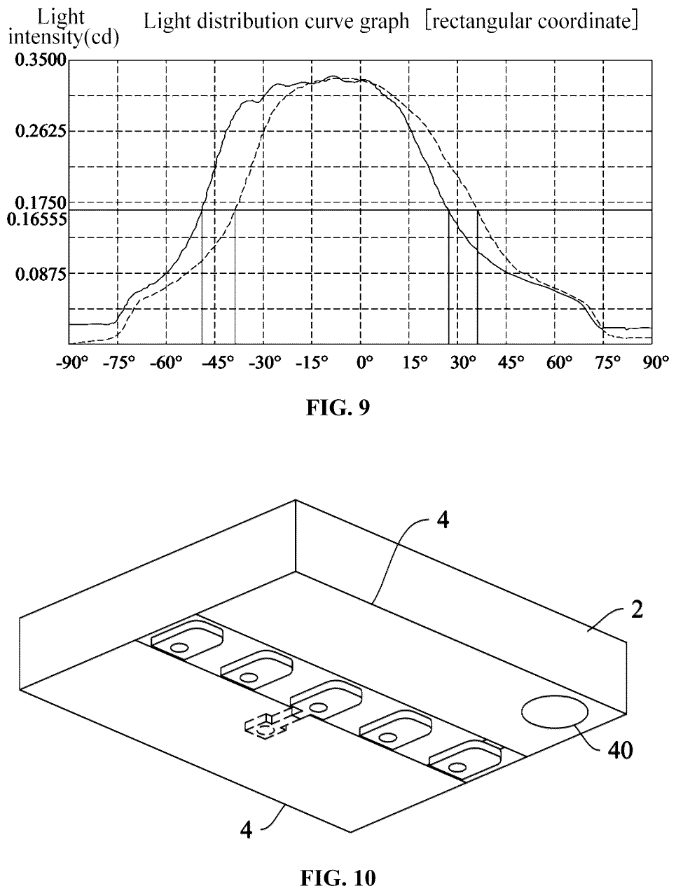

When the light-concentrating portion 31 includes the convex lens structure 310 and the annular bowl-cup structure 311, the light emission condition of the light-emitting device 1 is detected, the luminous flux of the light-emitting device 1 is detected to be 0.64181 m, and the luminous efficiency of the light-emitting device 1 is detected to be 17.881 m/W. The light distribution curve is obtained as shown in FIG. 8 and FIG. 9, the solid-line-shaped curve is a light distribution curve of the light-emitting device 1 detected at a first plane S1, the dotted-line-shaped curve is a light distribution curve of the light-emitting device 1 detected at a second plane S2, the second plane S2 is perpendicular to the first plane S1, and a straight line of intersection of the second plane S2 and the first plane S1 coincides with the optical axis L2 of the convex lens structure 310 (it should be understood that the straight line of intersection of the second plane S2 and the first plane S1 may generally substantially coincide with the optical axis L2 of the convex lens structure 310 due to the test errors, however, the straight line of intersection of the second plane S2 and the first plane S1 is difficult to completely coincide with the optical axis L2 of the convex lens structure 310 due to the test errors).

According to FIG. 8 and FIG. 9, it can be observed that for the light-emitting device 1, in the first plane S1, when the light-emitting intensity is half or more of a maximum light-emitting intensity, a light-emitting angle θ2 (50%) is 76.2°; for the light-emitting device 1, in the second plane S2, when the light-emitting intensity is half or more of the maximum light-emitting intensity, a light-emitting angle θ3 (50%) is 74.1°.

It should be noted that, when the light-emitting angle of the light rays emitted by the light-emitting device 1 ranges from 0° to 180° and the light-emitting intensity is half or more of the maximum light-emitting intensity, light beams having the light-emitting angle θ (50%) in the range of 60° to 90° are substantially formed into parallel light beams, moreover, the light-emitting angle θ (50%) of the light-emitting device 1 is the larger, then the light intensity distribution of the parallel light beams emitted by the light-emitting device 1 is relatively uniform. Therefore, the light-emitting angle θ (50%) of the light-emitting device 1 is preferably in a range of 60° to 90°, and the light-emitting angle θ (50%) of the light-emitting device 1 is more preferable as it is closer to 90°. Based on this, according to the detected light distribution curve shown in FIG. 8 and FIG. 9, it can be obtained that the light intensity distribution of the parallel light beams emitted by the light-emitting device 1 is relatively uniform.

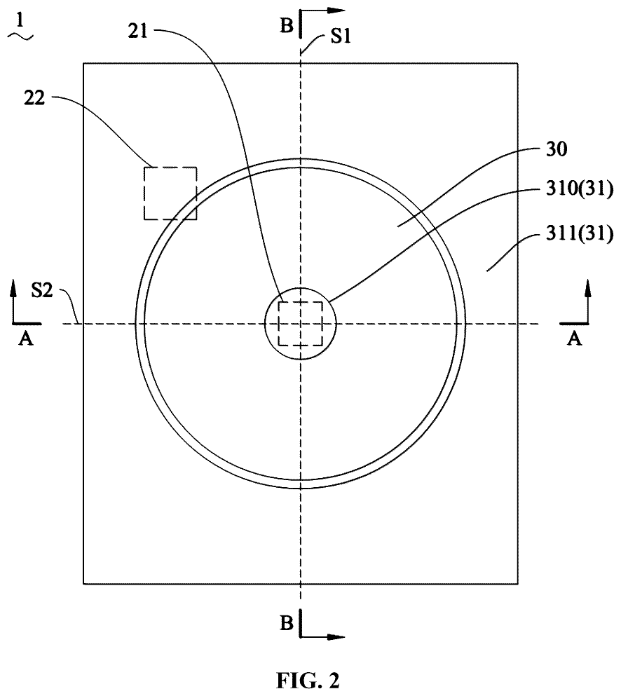

Referring to FIG. 2 to FIG. 5 again, optionally, the second surface 202 is a polygonal surface, and the light-emitting element 21 is located in a center of the second surface 202. Therefore, on the one aspect, more setting space exists at the outer periphery of the light-emitting element 21, so that at least part of light-concentrating portion 31 is disposed. On the other hand, after the light rays emitted by the light-emitting element 21 are concentrated by the light-concentrating portion 31, the light rays may be emitted approximately from the center of the light-emitting device 1, so that the light-emitting position of the light-emitting device 1 is more reasonable.

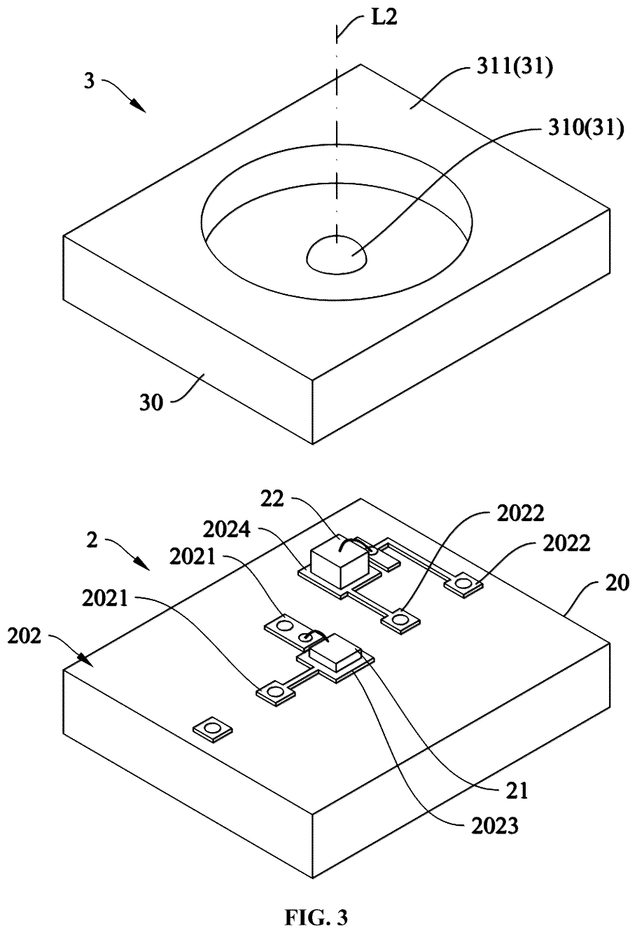

Since the second surface 202 is a polygonal surface, the second surface 202 has multiple corners. Preferably, the first photosensitive element 22 is located on a connection line between the light-emitting element 21 and a corner of the second surface 202, and the first photosensitive element 22 is spaced apart from the light-emitting element 21 and is located proximate to the corner. Therefore, a distance between the first photosensitive element 22 and the light-emitting element 21 may be relatively far, so that the light rays emitted by the light-emitting element 21 received by the first photosensitive element 22 are mainly light rays reflected from the interface between the light-transmissive encapsulation layer 30 and the air, in other words, the first photosensitive element 22 does not receive, as far as possible, light rays emitted from the light-emitting element 21 towards the light-concentrating portion 31, thereby reducing the influence of the first photosensitive element 22 on the light rays emitted by the light-emitting element 21, and improving the light-emitting intensity of the light-emitting device 1. As shown in FIG. 3, the second surface 202 is rectangular, the light-emitting element 21 is located in the center of the second surface 202, and the first photosensitive element 22 is approximately located on the connection line between the light-emitting element 21 and the corner of the second surface 202.

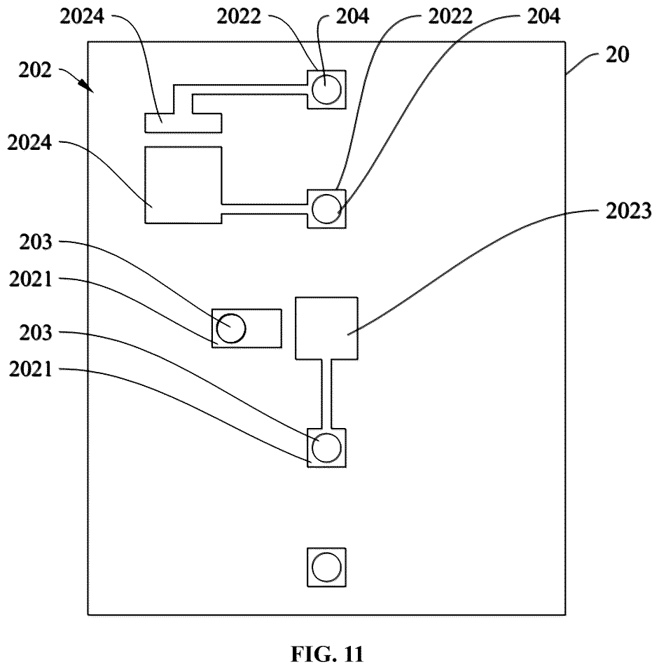

As shown in FIG. 3 to FIG. 5 and FIG. 10 to FIG. 12, optionally, the multiple first electrodes 2011 and the multiple second electrodes 2012 are arranged in a same straight line, so that the first electrodes 2011 and the second electrodes 2012 are arranged neatly, and the first electrodes 2011 and the second electrodes 2012 are simultaneously aligned and connected to electrical connection terminals of the external circuit.

Optionally, multiple third electrodes 2021 are disposed at intervals on the second surface 202, and a third electrode of the multiple third electrodes 2021 corresponds to a respective one of the multiple first electrodes 2011. In addition, the third electrode of the multiple third electrodes 2021 is electrically connected to respective one of the multiple first electrodes 2011 through the first conductive portion 203, and the light-emitting element 21 is electrically connected to the third electrode 2021, so that the light-emitting element 21 connected to the second surface 202 is electrically connected to the first electrode 2011 disposed on the first surface 201.

Optionally, the third electrode 2021, the first bracket 20, and the first electrode 2011 may be drilled as a whole, and then a conductive material, such as a conductive adhesive, is filled into a hole, or a conductive material is overlaid on a hole wall, for example, a copper plating is performed on the hole wall, to form the first conductive portion 203.

When the conductive material is overlaid on the hole wall, the conductive material cannot completely seal and block the hole. Therefore, optionally, after the conductive material is overlaid on the hole wall, the remaining hole may be filled with the insulation material (such as, insulation ink or insulation resin), so as to prevent impurities from entering the hole, so that the impurities are prevented from affecting the conductive performance of the conductive material, and even a situation that the conductive material is oxidized and corroded to cause the failure of the electrical connection function of the first conductive portion 203 is prevented.

Optionally, multiple fourth electrodes 2022 are disposed at intervals on the second surface 202, a fourth electrode of the multiple fourth electrode 2022 corresponds to a respective one of the multiple second electrodes 2012, the fourth electrode of the multiple fourth electrode 2022 is electrically connected to the respective one of the multiple second electrodes 2012 through the second conductive portion 204, and the first photosensitive element 22 is electrically connected to the fourth electrode 2022, so that the first photosensitive element 22 connected to the second surface 202 is electrically connected to the second electrode 2012 disposed on the first surface 201.

Optionally, the fourth electrode 2022, the first bracket 20, and the second electrode 2012 may be drilled as a whole, and then a conductive material, such as a conductive adhesive, is filled into a hole, or a conductive material is overlaid on a hole wall, for example, a copper plating is performed on the hole wall, to form the second conductive portion 204.

When the conductive material is overlaid on the hole wall, the conductive material cannot completely seal and block the hole. Therefore, optionally, after the conductive material is overlaid on the hole wall, the remaining hole may be filled with the insulation material (such as, insulation ink or insulation resin), so as to prevent impurities from entering the hole, so that the impurities are prevented from affecting the conductive performance of the conductive material, and even a situation that the conductive material is oxidized and corroded to cause the failure of the electrical connection function of the second conductive portion 204 is prevented.

Optionally, first pads 2023 that are spaced apart from the multiple third electrodes 2021 and the multiple fourth electrodes 2022 is further disposed on the second surface 202, the light-emitting element 21 is die-bonded to a first pad of the first pads 2023, two third electrodes 2021 are provided, the two third electrodes 2021 are located on two adjacent sides of a first pad of the first pads 2023, respectively, one third electrode of the two third electrodes 2021 is electrically connected to a respective one of the first pads 2023, the other third electrode of the two third electrodes 2021 is electrically connected to the light-emitting element 21 in a manner that includes, but is not limited to, a routing and a pin inserting, two first electrodes 2011 are provided, one first electrode of the two first electrodes 2011 is disposed opposite to one third electrode of the multiple third electrodes 2021 and is electrically connected to the one third electrode of the multiple third electrodes 2021 through the first conductive portion 203, the other first electrode of the two first electrodes 2011 is disposed opposite to a first pad of the first pads 2023, the first surface is further provided with a fifth electrode 2013 which is spaced apart from the first electrodes 2011 and the multiple second electrodes 2012, the fifth electrode 2013 is electrically connected to the other first electrode of the two first electrodes 2011, the fifth electrode 2013 is disposed opposite to the other third electrode of the two third electrodes 2021 and is electrically connected to the other third electrode 2021 through the first conductive portion 203, and the two first electrodes 2011 and the multiple second electrodes 2012 are arranged along a middle line of the first surface 201, so that a positive electrode of the light-emitting element 21 may be electrically connected to one third electrode of the two third electrodes 2021, and a negative electrode of the light-emitting element 21 may be electrically connected to the other third electrode of the two third electrodes 2021. In the two third electrodes 2021, one third electrode 2021 is electrically connected to the first electrode 2011 through the first conductive portion 203, and the other third electrode 2021 is electrically connected to the first electrode 2011 through the first conductive portion 203 and the fifth electrode 2013 in sequence, so that the two first electrodes 2011 and the multiple second electrodes may be arranged along the middle line of the first surface 201, whereby the first electrode 2011 and the second electrode 2021 are arranged neatly, and the first electrode 2011 and the second electrode 2012 are simultaneously aligned and connected to the electrical connection terminal of the external circuit.

Optionally, the fourth electrode 2022 is disposed opposite to the corresponding second electrode 2012, multiple second pads 2024 that are spaced apart from the third electrodes 2021 and the fourth electrodes 2024 are further disposed on the second surface 202, a second pad of the multiple second pads 2024 is electrically connected to a respective one of the multiple fourth electrodes 2022, and the first photosensitive element 22 is electrically connected to a second pad of the multiple second pads 2024.

Optionally, the first photosensitive element 22 is die-bonded to one second pad 2024 of the multiple second pads 2024, and moreover, one electrical connection terminal of the first photosensitive element 22 is electrically connected to the one second pad 2024. Other electrical connection terminals of the first photosensitive element 22 is separately electrically connected to other second pads 2024 in a manner that includes, but is not limited to, a routing and a pin inserting, so as to reduce the degree of complexity of electrical connection between the first photosensitive element 22 and the second pad 2024, where the electrical connection terminal of the first photosensitive element 22 may include, but is not limited to, a positive electrode, a negative electrode, a grounding terminal, a base terminal, a collector terminal, and an emitter terminal.

Exemplarily, the first photosensitive element 22 has two electrical connection terminals, that is, a positive terminal and a negative terminal. Correspondingly, two second pads 2024 are provided, and two fourth electrode 2022 are provided. The first photosensitive element 22 is die-bonded to the second pad 2024, and one electrical connection terminal is electrically connected to the one second pad 2024. The other electrical connection terminal of the first photosensitive element 22 is electrically connected to the other second pad 2024 in a manner that includes, but is not limited to, a routing and a pin inserting, and the two fourth electrodes 2022 are respectively electrically connected to the two second electrodes 2022 through the second conductive portion 204.

Optionally, a grounding electrode 2014 and a grounding extension portion 2015 that are spaced from the first electrodes 2011 and the second electrodes 2012 are further disposed on the first surface 201, and the grounding electrode 2014, the multiple first electrodes 2011, and the multiple second electrodes 2012 are arranged in a same straight line. The grounding extension portion 2015 is electrically connected to the grounding electrode 2014, so that a certain blocking function of electromagnetic waves can be implemented by using the grounding extension portion 2015. On the one hand, the interference of the external electromagnetic wave to the light-emitting device 1 is reduced, the interference of the electromagnetic waves emitted by the light-emitting device 1 itself to the external electronic device is reduced, and the accuracy of the light-emitting condition of the light-emitting device 21 detected by the first photosensitive element 22 is improved, whereby the light-emitting intensity of the light-emitting device 21 can be stably maintained within the ideal light intensity range for a long time. On the other hand, the electrostatic protection function can be implemented, so as to prolong the service life of the light-emitting device 1.

Preferably, conductive devices (such as, the first electrode 2011, the second electrode 2012, the third electrode 2021, the fourth electrode 2022, the fifth electrode 2013, the grounding electrode 2014, the first conductive portion 203, the second conductive portion 204, the first pad 2023, the second pad 2024, and the grounding extension portion 2015) disposed on the first bracket 20 are not exposed to the outer periphery of the first bracket 20, so that the leakage current on the outer peripheral surface of the light-emitting element 2 can be prevented, and thus the generation of interference signals caused by the external interference current or the output leakage current received by the light-emitting assembly 2 can be prevented.

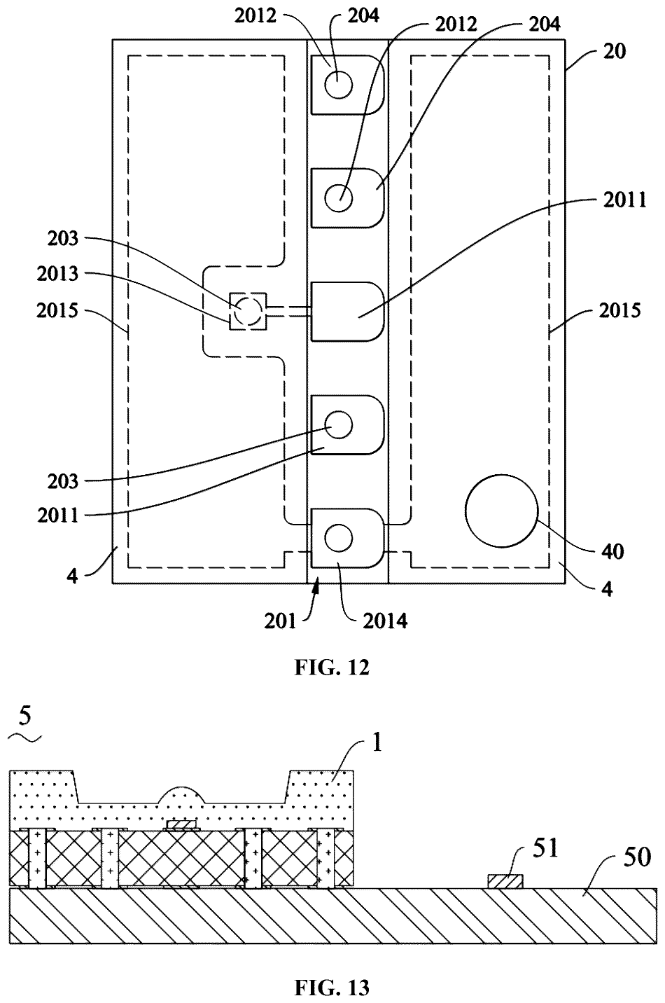

Optionally, an insulation isolation layer 4 may further be disposed on a side of the light-emitting assembly 2 facing away from the light-transmissive encapsulation layer 30. The insulation isolation layer 4 may include, but is not limited to, an insulation material such as plastic, resin, and insulation ink. The insulation isolation layer 4 is spaced from the grounding electrode 2014, the first electrode 2011 and the second electrode 2012, so as to avoid the fifth electrode 2013 and the grounding extension portion 2015 from being electrically connected to the external electrical connection terminal through the insulation isolation layer 4, thereby avoiding the electrical connection caused by the accidental contact between the fifth electrode 2013 and the grounding extension portion 2015 and the external circuit. A fifth electrode 2013 shielded by the insulation isolation layer 4 is shown in a dashed line in FIG. 10, and the fifth electrode 2013 and the grounding extension portion 2015 shielded by the insulation isolation layer 4 are shown in a dashed line in FIG. 12.

Optionally, the insulation isolation layer 4 may include ink, so that the insulation isolation layer 4 may also cover the fifth electrode 2013 and the grounding extension portion 2015, so that the appearance of the light-emitting device 1 is more simplified.

Preferably, an indication portion 40 may be further disposed on a side of the insulation isolation layer 4 facing away from the light-emitting assembly 2. The indication portion 40 may have different colors or reflectivity from the insulation isolation layer 4, and the indication portion 40 may be disposed in correspondence with the grounding electrode 2014 to indicate a position of the grounding electrode 2014, so that when the light-emitting device 1 is electrically connected to the external circuit, positions of the grounding electrode 2014 of the light-emitting device 1, the first electrode 2011 of the light-emitting device 1, and the second electrode 2012 of the light-emitting device 1 may be determined by using the indication portion 40, whereby the grounding electrode 2014 of the light-emitting device 1, the first electrode 2011 of the light-emitting device 1, and the second electrode 2012 of the light-emitting device 1 are electrically connected to electrical connection terminals of the external circuit, separately.

As shown in FIG. 13, the present disclosure further provides a photoelectric sensor 5. The photoelectric sensor 5 includes a second bracket 50, a second photosensitive element 51, and the light-emitting device 1 provided in the foregoing technical schemes. The second bracket 50 carries a detection circuit (not shown in the drawings), and the second photosensitive element 51 may include, but is not limited to, a photoresistor, a photodiode, and a phototransistor, so that the light rays may be received, and the current flowing through the second photosensitive element 51 changes with the change of the light rays. The second photosensitive element 51 and the light-emitting device 1 are disposed at intervals on the second bracket 50, and the second photosensitive element 51 and the light-emitting device 1 are separately electrically connected to the detection circuit. The light-emitting device 1 may emit light rays towards the outside of the photoelectric sensor 5, and the light rays are enabled to be reflected by the external environment and emitted towards the second photosensitive element 51. Since the light-emitting intensity of the light-emitting device 1 can be stably maintained within the ideal light intensity range for a long time, the accuracy of the photoelectric sensor 5 can be easily maintained at a high level.

In the description herein, it should be understood that the orientation or position relationships indicated by terms “above”, “below”, “left”, “right”, and the like are based on the orientation or position relationships shown in the drawings, merely for case of description and simplifying an operation, these relationships do not indicate or imply that the referred device or element has a specific orientation and is constructed and operated in a specific orientation, and thus it is not to be construed as limiting the present disclosure. In addition, the terms “first” and “second” are used only to distinguish between descriptions and have no special meaning.

It should be noted that in the description of this specification, the terms “one embodiment”, “example” and the like mean that specific features, specific structures, specific materials, or specific characteristics described in connection with this embodiment or example are included in at least one embodiment or example of the present disclosure. In this specification, illustrative expressions of these terms do not necessarily refer to the same embodiment or example.

In addition, it should be understood that, although this specification is described according to an implementation manner, not each implementation manner includes only one independent technical scheme. This description manner of the specification is for clarity only. Those skilled in the art should use the specification as a whole, and the technical schemes in the embodiments may be appropriately combined to form other implementation manners that may be understood by those skilled in the art.

In this disclosure, both the light-emitting element and the first photosensitive element are disposed on the first bracket, and the light-emitting element and the first photosensitive element are encapsulated together by using the light-transmissive encapsulation layer included in the light-transmissive component, so that the light rays emitted by the light-emitting element may be propagated to the first photosensitive element through the light-transmissive encapsulation layer, whereby the first photosensitive element can collect the sufficient amount of light rays emitted by the light-emitting element, and the light-emitting intensity of the light-emitting element can be stably maintained within the ideal light intensity range for a long time.

Further, the light-transmissive component includes the light-concentrating portion disposed on the side of the light-transmissive encapsulation layer facing away from the light-emitting assembly, so as to concentrate the light rays emitted by the light-emitting element, so that the light rays emitted by the light-emitting device approximate the parallel light without affecting the first photosensitive element to collect the light rays emitted by the light-emitting element.

What is claimed is:

1. A light-emitting device, comprising:
a light-emitting assembly, wherein the light-emitting assembly comprises a first bracket, a light-emitting element, and a first photosensitive element, wherein the first bracket has a first surface and a second surface opposite to each other, a plurality of first electrodes and a plurality of second electrodes are disposed at intervals on the first surface, the light-emitting element and the first photosensitive element are disposed at intervals on the second surface, the light-emitting element is electrically connected to at least one of the plurality of first electrodes, and the first photosensitive element is electrically connected to at least one of the plurality of second electrodes; and
a light-transmissive component, wherein the light-transmissive component comprises a light-transmissive encapsulation layer and a light-concentrating portion, the light-transmissive encapsulation layer is covered on a side of the light-emitting assembly facing away from the first surface, the light-concentrating portion is disposed on a side of the light-transmissive encapsulation layer facing away from the light-emitting assembly, the light-concentrating portion is disposed in correspondence with the light-emitting element, and the light-concentrating portion is configured to concentrate light emitted by the light-emitting element.

2. The light-emitting device of claim 1, wherein the light-emitting element has a first central axis; and
the light-concentrating portion includes a convex lens structure, an optical axis of the convex lens structure is at a distance d1 from the first central axis, wherein 0 mm≤d1≤0.05 mm.

3. The light-emitting device of claim 1, wherein the light-concentrating portion comprises a convex lens structure and an annular bowl-cup structure, an optical axis of the convex lens structure is at a distance d1 from a first central axis of the light-emitting element, wherein 0 mm≤d1≤0.05 mm, an inner side surface of the bowl-cup structure is spaced apart from the convex lens structure, and the inner side surface of the bowl-cup structure correspondingly surrounds an outer periphery of the convex lens structure.

4. The light-emitting device of claim 1, wherein the second surface is a polygonal surface, the light-emitting element is located in a center of the second surface, the first photosensitive element is located on a connection line between the light-emitting element and a corner of the second surface, and the first photosensitive element is spaced apart from the light-emitting element and is located proximate to the corner.

5. The light-emitting device of claim 1, wherein the plurality of first electrodes and the plurality of second electrodes are arranged in a same straight line.

6. The light-emitting device of claim 1, wherein a plurality of third electrodes and a plurality of fourth electrodes are disposed at intervals on the second surface, each of the plurality of third electrodes corresponds to a respective one of the plurality of first electrodes, each of the plurality of third electrodes is electrically connected to a respective one of the plurality of first electrodes through a first conductive portion, the light-emitting element is electrically connected to at least one of the plurality of third electrodes, each of the plurality of fourth electrodes corresponds to a respective one of the plurality of second electrodes, each of the plurality of fourth electrodes is electrically connected to a respective one of the plurality of second electrodes through a second conductive portion, and the first photosensitive element is electrically connected to at least one of the plurality of fourth electrodes.

7. The light-emitting device of claim 6, wherein a first pad that is spaced apart from the plurality of third electrodes and the plurality of fourth electrodes is further disposed on the second surface, the light-emitting element is die-bonded to the first pad, two third electrodes are provided, the two third electrodes are located on two adjacent sides of the first pad, respectively, one third electrode of the two third electrodes is electrically connected to the first pad, two first electrodes are provided, one first electrode of the two first electrodes is disposed opposite to one third electrode of the two third electrodes and is electrically connected to the one third electrode of the two third electrodes through a first conductive portion, another first electrode of the two first electrodes is disposed opposite to the first pad, the first surface is further provided with a fifth electrode spaced apart from the two first electrodes and the plurality of second electrodes, the fifth electrode is electrically connected to the another first electrode of the two first electrodes, the fifth electrode is disposed opposite to another third electrode of the two third electrodes and is electrically connected to the another third electrode through a first conductive portion, and the two first electrodes and the plurality of second electrodes are arranged along a middle line of the first surface.

8. The light-emitting device of claim 1, wherein a grounding electrode and a grounding extension portion that are spaced from the plurality of first electrodes and the plurality of second electrodes are further disposed on the first surface, the grounding electrode, the plurality of first electrodes and the plurality of second electrodes are arranged in a same straight line, and the grounding extension portion is electrically connected to the grounding electrode.

9. The light-emitting device of claim 1, wherein a material of the light-transmissive encapsulation layer is the same as a material of the light-concentrating portion, and the light-transmissive encapsulation layer and the light-concentrating portion are integrally formed.

10. The light-emitting device of claim 1, wherein the light-concentrating portion includes an annular bowl-cup structure, and an inner side surface of the bowl-cup structure surrounds a first central axis of the annular bowl-cup structure.

11. The light-emitting device of claim 2, wherein the light-concentrating portion includes an annular bowl-cup structure, and an inner side surface of the bowl-cup structure surrounds the first central axis.

12. The light-emitting device of claim 6, wherein each of the plurality of fourth electrodes is disposed opposite to a respective one of the plurality of second electrodes, a plurality of second pads that are spaced apart from the plurality of third electrodes and the plurality of fourth electrodes are further disposed on the second surface, each of the plurality of second pads is electrically connected to a respective one of the plurality of fourth electrodes, and the first photosensitive element is electrically connected to each of the plurality of second pads.

13. The light-emitting device of claim 7, wherein each of the plurality of fourth electrodes is disposed opposite to a respective one of the plurality of second electrodes, a plurality of second pads that are spaced apart from the plurality of third electrodes and the plurality of fourth electrodes are further disposed on the second surface, each of the plurality of second pads is electrically connected to a respective one of the plurality of fourth electrodes, and the first photosensitive element is electrically connected to each of the plurality of second pads.

14. A photoelectric sensor, comprising a second bracket, a second photosensitive element, and the light-emitting device of claim 1, wherein the second bracket carries a detection circuit, the second photosensitive element and the light-emitting device are disposed at intervals on the second bracket, the second photosensitive element and the light-emitting device are respectively electrically connected to the detection circuit, the light-emitting device is configured to emit light toward an outside of the photoelectric sensor to enable light be reflected through an external environment towards the second photosensitive element.

15. The photoelectric sensor of claim 14, wherein the light-emitting element has a first central axis; and
the light-concentrating portion includes a convex lens structure, an optical axis of the convex lens structure is at a distance d1 from the first central axis, wherein 0 mm≤d1≤0.05 mm.

16. The photoelectric sensor of claim 14, wherein the light-concentrating portion comprises a convex lens structure and an annular bowl-cup structure, an optical axis of the convex lens structure is at a distance d1 from a first central axis of the light-emitting element, wherein 0 mm≤ d1≤0.05 mm, an inner side surface of the bowl-cup structure is spaced apart from the convex lens structure, and the inner side surface of the bowl-cup structure correspondingly surrounds an outer periphery of the convex lens structure.

17. The photoelectric sensor of claim 14, wherein the second surface is a polygonal surface, the light-emitting element is located in a center of the second surface, the first photosensitive element is located on a connection line between the light-emitting element and a corner of the second surface, and the first photosensitive element is spaced apart from the light-emitting element and is located proximate to the corner.

18. The photoelectric sensor of claim 14, wherein the plurality of first electrodes and the plurality of second electrodes are arranged in a same straight line.

19. The photoelectric sensor of claim 14, wherein a plurality of third electrodes and a plurality of fourth electrodes are disposed at intervals on the second surface, each of the plurality of third electrodes corresponds to a respective one of the plurality of first electrodes, each of the plurality of third electrodes is electrically connected to a respective one of the plurality of first electrodes through a first conductive portion, the light-emitting element is electrically connected to at least one of the plurality of third electrodes, each of the plurality of fourth electrodes corresponds to a respective one of the plurality of second electrodes, each of the plurality of fourth electrodes is electrically connected to a respective one of the plurality of second electrodes through a second conductive portion, and the first photosensitive element is electrically connected to at least one of the plurality of fourth electrodes.

20. The photoelectric sensor of claim 19, wherein a first pad that is spaced apart from the plurality of third electrodes and the plurality of fourth electrodes is further disposed on the second surface, the light-emitting element is die-bonded to the first pad, two third electrodes are provided, the two third electrodes are located on two adjacent sides of the first pad, respectively, one third electrode of the two third electrodes is electrically connected to the first pad, two first electrodes are provided, one first electrode of the two first electrodes is disposed opposite to one third electrode of the two third electrodes and is electrically connected to the one third electrode of the two third electrodes through a first conductive portion, another first electrode of the two first electrodes is disposed opposite to the first pad, the first surface is further provided with a fifth electrode spaced apart from the two first electrodes and the plurality of second electrodes, the fifth electrode is electrically connected to the another first electrode of the two first electrodes, the fifth electrode is disposed opposite to another third electrode of the two third electrodes and is electrically connected to the another third electrode through a first conductive portion, and the two first electrodes and the plurality of second electrodes are arranged along a middle line of the first surface.
